(19) United States
(12) Patent Application Publication
(10) Pub. No.: US 2006/0098765 A1
(43) Pub. Date: May 11, 2006

(54) Interference cancellation in RFID systems

(75) Inventors: Michael H. Thomas, Bellevue, WA (US); William T. Colleran, Seattle, WA (US); Erik C. Fountain, Rancho Santa Margarita, CA (US); Todd E. Humes, Shoreline, WA (US)

Correspondence Address: Lawrence E Lycke;Merchant & Gould P.C., P.O. Box 2903, minneapolis, MN, 55402, US

(73) Assignee: Impinj, Inc., Seattle, WA (US)

(21) Appl. No.: 10/981,893

(22) Filed: Nov. 5, 2004

(51) Int. Cl. H03D 1/04; H04B 1/38

(52) U.S. Cl. 375/346; 375/219

(57) ABSTRACT

An interference canceller for a RFID reader senses a signal related to the interference signal in the receive path of the reader. The canceller outputs an adjustment signal that depends on the sensed signal, which is coupled into the receive path before a downconverter in the receive path. The canceller can use a signal derived from the transmit path in generating the adjustment signal. The canceller adjusts the amplitude or phase (or both) of the derived signal to form the adjustment signal so that it cancels a carrier feed-through interference signal when injected into the receive path. The canceller can include a vector modulator to adjust the amplitude and/or phase of the derived signal; or alternatively, the canceller can include a variable attenuator and a variable phase shifter to adjust the amplitude and/or phase of the derived signal. The loop can be continuous or non-continuous.

### FIELD

The present invention is related to the field of Radio Frequency IDentification (RFID) systems, and more specifically to interference cancellation in RFID readers.

### BACKGROUND

Radio Frequency IDentification (RFID) systems can be used in many ways for locating and identifying objects. RFID systems are particularly useful in product-related and service-related industries for tracking large numbers of objects are being processed, inventoried, or handled. In such applications, an RFID tag is usually attached to individual items, or to their packages or containers.

In principle, RFID techniques entail using a device called an RFID reader to interrogate one or more RFID tags. Interrogation is performed by the reader transmitting a Radio Frequency (RF) wave. A tag that senses the interrogating RF wave responds by transmitting back another RF wave, a process known as backscatter. Backscatter may take place in a number of ways. The response may further encode a number stored internally in the tag. The response, and the number if available, is decoded by the reader, which thereby identifies, counts, or otherwise interacts with the associated item. The number can denote a serial number, a price, a date, a destination, other attribute(s), any combination of attributes, and so on. Some RFID tags generate the backscatter so that its spectrum straddles a carrier signal frequency.

An RFID tag typically includes an antenna system, a radio section, a logical section, and a memory. Advances in semiconductor technology have miniaturized the electronics so much that an RFID tag can generate the backscatter while powered by only the RF signal it receives, enabling some RFID tags to operate without a battery.

An RFID reader typically includes a transceiver. The transmit portion of the transceiver provides a relatively high power carrier signal. The carrier signal may “feed-through” to receive portion of the transceiver, causing undesirable distortion of the received signal and DC offsets in the demodulated signals.

### SUMMARY

In accordance with the various described embodiments of the present invention, an interference canceller for a RFID reader is provided. In some embodiments, the canceller senses a signal related to the interference signal in the receive path of the reader. The receive path includes a downconverter. The canceller outputs an adjustment signal that depends on the sensed signal, which is coupled into the receive path before the downconverter. By providing cancellation in the receive path before downconversion, the downconverter can be designed to have a relatively small dynamic range without becoming saturated. This can reduce the complexity and cost of the reader. Further, the relatively large transients caused by the carrier feed-through signals as they propagate to the downconverter are eliminated relatively early in the receive process, which can help avoid other noise-related problems in the operation of the reader. Still further, some embodiments do not require a replica path to generate a cancellation signal, which can reduce the cost of the reader.

In some embodiments, the canceller uses a signal derived from the transmit path in generating the adjustment signal. The canceller adjusts the amplitude or phase (or both) of the derived signal to form the adjustment signal so that it cancels a carrier feed-through interference signal when injected into the receive path.

In some other embodiments, the canceller uses in-phase and quadrature component signals in sensing the interference signal. The in-phase and quadrature component signals serve as an error signal in a feedback loop, which can be implemented in hardware using loop filter units. The canceller can also include a vector modulator to adjust the amplitude and/or phase of the derived signal. In an alternative embodiment, the canceller includes a variable attenuator and a variable phase shifter to adjust the amplitude and/or phase of the derived signal.

In still another embodiment, the feedback loop is implemented in software executed by a processor included in the reader. In some alternative embodiments, the loop need not be continuous (e.g., having fixed settings or settings that can be updated as needed or according to a schedule).

### BRIEF DESCRIPTION OF THE DRAWINGS

Non-limiting and non-exhaustive embodiments are described with reference to the following figures, wherein like reference numerals refer to like parts throughout the various views unless otherwise specified.

FIG. 1 is a block diagram illustrating an RFID system with a reader having a canceller, according to one embodiment of the present invention.

FIG. 2 is a block diagram illustrating in more detail the transceiver with antenna unit, according to one embodiment of the present invention.

FIG. 3 is a block diagram illustrating the interconnection of the canceller with other components of the transceiver of FIG. 2, according to one embodiment of the present invention.

FIG. 4 is a flow diagram illustrating operational flow of a canceller in canceling an interference signal, according to one embodiment of the present invention.

FIG. 5 is block diagram illustrating a Cartesian-based canceller, according to one embodiment of the present invention.

FIG. 6 is block diagram illustrating a Cartesian-based canceller, according to another embodiment of the present invention.

FIG. 7 is block diagram illustrating a polar-based canceller, according to one embodiment of the present invention.

### DETAILED DESCRIPTION

Various embodiments are directed to a system, method and apparatus to cancel an interference signal in which the data signal spectrum of a modulated carrier signal is relatively close to the carrier frequency. For example, this scenario occurs in some RFID systems.

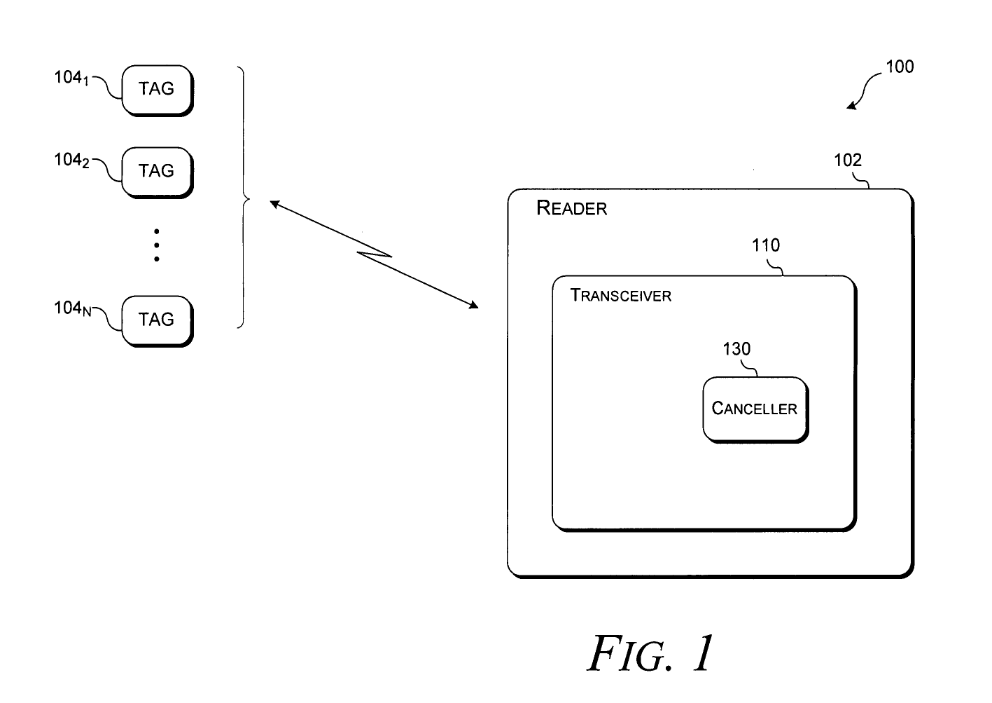

FIG. 1 illustrates an RFID system 100, according to one embodiment of the present invention. In this embodiment, system 100 includes a reader 102 and tags 104₁, 104₂, . . . , and 104_{N}. Reader 102 includes a transceiver 110. Further, in accordance with this embodiment, transceiver 110 includes a canceller 130 that is configured to provide and combine an adjustment signal with a received signal to reduce the effects of an interference signal coupled into the received signal. Various embodiments for providing an adjustment signal and combining the adjustment signal with an interference signal are described below.

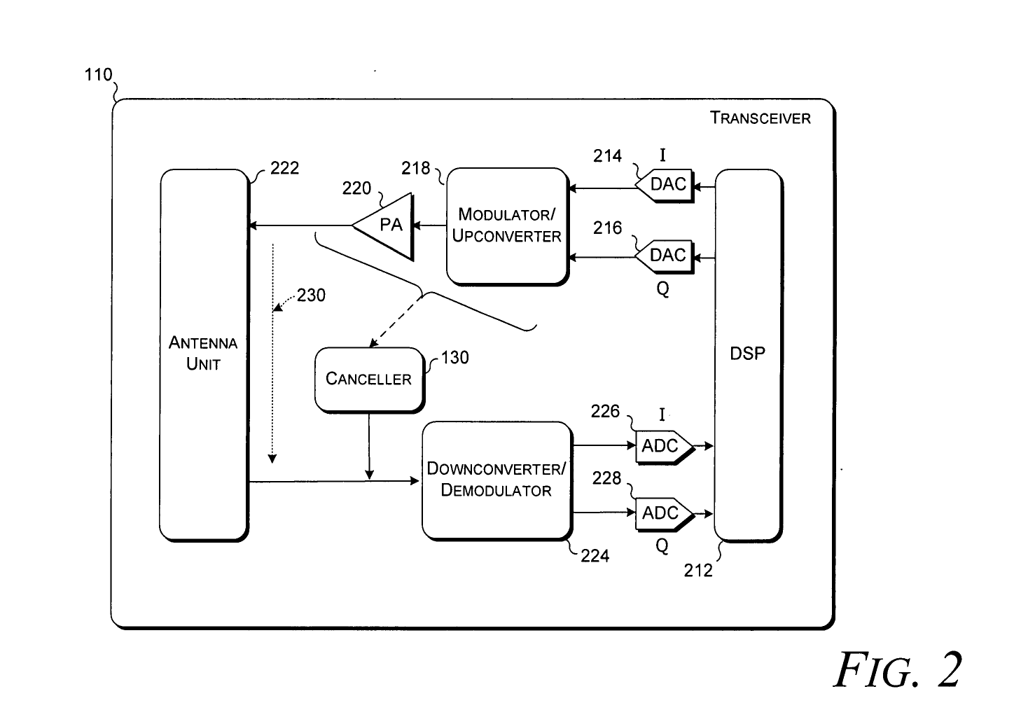

For example, in RFID system 100, the interference signal includes the aforementioned carrier feed-through (i.e., coupling of the carrier signal into receive path propagating the received backscatter signal). In addition, the interference signal may include noise, such as that from a non-coherent noise sources. In this example, canceller 130 is configured to provide the adjustment signal so that when combined with the received backscatter signal, the adjustment signal and the carrier feed-though signal destructively interfere or cancel. In the ideal case, the magnitude of adjustment signal would exactly match that of the carrier feed-through signal, while the phase of the adjustment signal would be exactly π radians out-of-phase with the carrier feed-through signal. In this way, the net energy of the combined adjustment and interference signals would be zero. In a typical application, the cancellation would result in a relatively small net energy. One embodiment of transceiver 110 is described in more detail in conjunction with FIG. 2 below. However, even though an RFID system example is described above, other embodiments of canceller 130 can be used in other RF systems.

FIG. 2 illustrates an embodiment of transceiver 110, suitable for use in RFID system 100 (FIG. 1) or other carrier-based RF system. In this embodiment, transceiver 110 includes a digital signal processor (DSP) 212, digital-to-analog converters (DACs) 214 and 216, a modulator/upconverter 218, a power amplifier (PA) 220, an antenna unit 222, a downconverter/demodulator 224, and analog-to-digital converters (ADCs) 226 and 228. In this embodiment, modulator/upconverter 218, PA 220, antenna unit 222 and the propagation mediums (e.g., waveguide, stripline, microstrip, etc.) interconnecting them are also referred herein as the transmit path. Similarly, downconverter/demodulator 224, filters and/or amplifiers (if any) between downconverter/demodulator 224 and antenna unit 222, and the propagation mediums interconnecting them and antenna unit 222 are referred to herein as the receive path. Although this embodiment of transceiver 110 implements a direct-conversion receiver, other embodiments may include an intermediate frequency (IF) stage.

In this embodiment, canceller 130 advantageously avoids the use of a replica path to generate an adjustment signal, thereby reducing complexity and cost compared to cancellation systems that require a replica path.

In operation during a transmit mode, DSP 212 provides in-phase (I) and quadrature (Q) digital data to DACs 214 and 216, respectively. DACs 214 and 216 each convert the received digital data to an analog signal having a voltage (or current in other embodiments) that depends on the digital data. Modulator/upconverter 218 then receives the analog I and Q data signals and performs quadrature modulation to modulate the data onto a carrier signal. In some embodiments, the carrier signal is generated by a local oscillator (LO). In one embodiment, modulator/upconverter 218 uses a vector modulator to perform quadrature modulation to modulate M bits onto the carrier signal using a single “symbol” to be transmitted. In other embodiments, other suitable modulators and/or modulations schemes can be used in implementing modulator/upconverter 218. Although quadrature modulation well known in the art, a brief description of quadrature modulation is provided using modulator 218 and DACs 214 and 216.

The M bits correspond to 2_{M} possible values for the symbol to be modulated on the carrier signal and transmitted. In one example embodiment, each of the possible values is mapped to a preselected set of ranges; i.e., a range of amplitude values of the carrier signal and a range of phase values of the carrier signal. For each set of M bits, DSP 212 provides digital input signals to DACs 214 and 216 so that DACs 214 and 216 output analog signals that cause modulator/upconverter 218 to modulate the phase and amplitude of the carrier signal to fall into the set of ranges of the symbol corresponding to that the set of M bits. For example, responsive to the analog signal received from DAC 214, modulator/upconverter 218 generates an I component signal (e.g., A₁ cos(ω_{C}t), where A₁ is the amplitude of the I component signal and ω_{C} is the carrier frequency) with the amplitude A₁ being dependent on the magnitude (e.g., voltage) of the analog signal from DAC 214.

Similarly, responsive to the analog signal received from DAC 216, modulator/upconverter 218 generates a Q component signal (e.g., as A₂ sin((ω_{C}t), where A₂ is the amplitude of the Q component signal) with the amplitude A₂ being dependent on the magnitude of the analog signal from DAC 216. Because the I and Q signals are based on cosine and sine signals respectively, the I and Q signals are orthogonal and, with proper scaling, can be combined to form a signal with any arbitrary amplitude and phase. Modulator/upconverter 218 then combines the I and Q component signals, so that the resulting signal has an amplitude and a phase that fall within the respective ranges of the desired symbol.

PA 220 then receives the output signal from modulator/upconverter 218 and amplifies it for broadcast via antenna unit 222. In some embodiments, antenna unit 222 includes a duplexer (e.g., directional coupler, circulator, etc.) so that a single antenna can be used for both transmitting and receiving RF signals. In other embodiments, antenna unit 222 may include separate transmit and receive antennas.

As previously described, carrier feed-through (indicated by a dashed arrow 230 in FIG. 2) may undesirably occur from the transmit path into the receive path. For example, the carrier feed-through may occur across a directional coupler in single antenna embodiments. In multiple antenna embodiments, carrier feed-through may occur from reflections of the carrier signal or directly from side lobes of the transmission beam when the transmitter transmits the carrier signal. In accordance with this embodiment of the invention, canceller 130 is configured to derive a signal from the transmit path, as indicated by the bracket dashed arrow in FIG. 2. Canceller 130 then processes the derived signal to form an adjustment signal, which is then coupled into the receive path between downconverter/demodulator 224 and antenna unit 222 to cancel the interference signal that was coupled into the receive path. However, in some embodiments the interference signal may include noise, such as from non-coherent sources. One such non-coherent source is a modulator in the transmit path. For example, in this embodiment modulator/upconverter 218 may be a non-coherent noise source. This noise can then be part of the interference signal and can be included in the downconverted signal outputted by downconverter/demodulator 224.

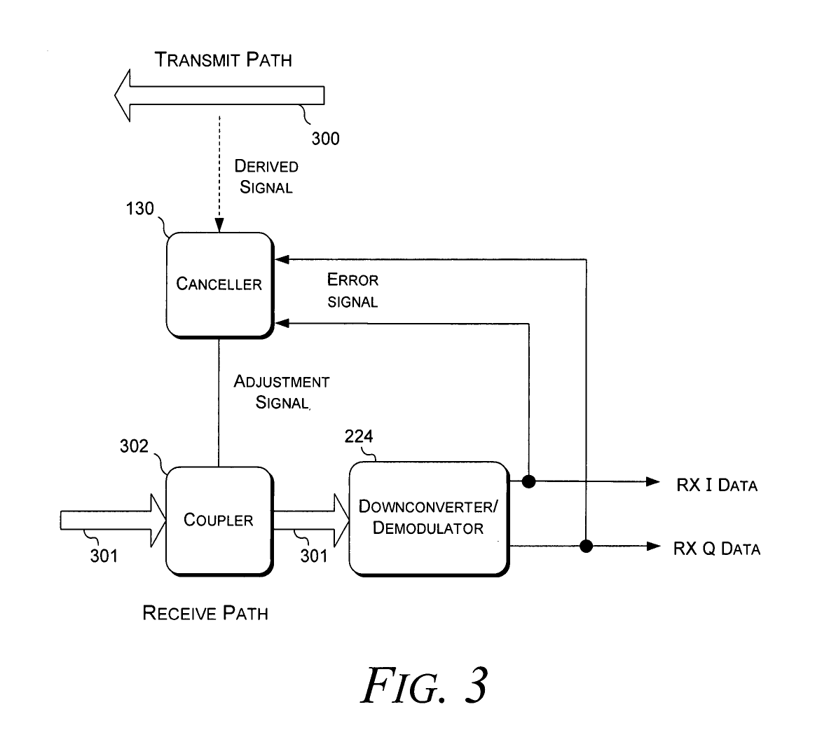

In this example application, the interference signal to be cancelled is the carrier feed-through previously described. Thus, in one embodiment, canceller 130 obtains the derived signal by coupling a relatively small portion of the carrier signal from the transmit path between PA 220 and antenna unit 222. In other embodiments, canceller 130 obtains the derived signal from the LO used to generate the carrier signal. Canceller 130 then adjusts the amplitude and phase of the derived signal to form the adjustment signal so that when the adjustment signal is coupled into the receive path, the adjustment signal will cancel the carrier feed-through signal. Schemes used to appropriately adjust the adjustment signal are described below in conjunction with FIGS. 3-8 for various embodiments of canceller 130. Although the embodiments described above derive the adjustment signal from the transmit path, other embodiments can derive the adjustment signal using other techniques.

In some RFID applications, an unmodulated or continuous wave carrier signal is transmitted during a receive mode to provide a carrier signal that tags 104₁-104_{N} may modulate (i.e. backscatter) and from which tags 104₁-104_{N} may scavenge power. In this receive mode, downconverter/demodulator 224 receives a backscatter signal via antenna unit 222. In one embodiment, downconverter/demodulator 224 form a direct conversion receiver to directly obtain baseband I and Q components signals from the received backscatter signal. ADCs 226 and 228 convert the received I and Q component signals to digital signals, which are then processed by DSP 212 to extract data modulated on the carrier signal by one of tags 104₁-104_{N}. In some embodiments, tags 104₁-104_{N} use the same modulation scheme as transceiver 110, although in other embodiments they may be different.

Embodiments of canceller 130 of transceiver 110 can provide several advantages over other techniques used to solve interference problems. For example, by providing cancellation in the receive path before downconverter/demodulator 224, the performance of transceiver 110 can be improved and/or the complexity and cost of transceiver 110 can be reduced. Without cancellation before downconverter/demodulator 224, carrier feed-through signals will reach downconverter/demodulator 224. As a result, downconverter/demodulator 224 will undesirably output the I and Q component signals with a relatively large DC component. Further, because the backscatter signals are typically small relative to the carrier feed-through signal, downconverter/demodulator 224 and/or the LNA should have a relatively large dynamic range or else become saturated, resulting in distortion of the received signal. Increasing the dynamic range of these components can significantly increase complexity and cost of transceiver 110 (FIG. 2). Further, the relatively large transient signals caused by the carrier feed-through signals as they propagate through the LNA and/or downconverter/demodulator 224 may cause other noise-related problems in the demodulation process or other parts of transceiver 110.

FIG. 3 illustrates the interconnection of canceller 130 (FIG. 2) within transceiver 110 (FIG. 1), according to one embodiment. In this embodiment, canceller 130 is coupled to derive a signal from transmit path 300. As previously stated, the transmit path can include the LO (not shown), PA 220 (FIG, 2), antenna unit 222 (FIG. 2) and the propagation mediums used to interconnect these components. The derived signal is represented as a dashed arrow in FIG. 3. Canceller 130 is also connected to a receive path 301 and, in particular, to a coupler 302 which is part of receive path 301. Coupler 302 is used to couple or inject the adjustment signal provided by canceller 130 into receive path 301 before downconverter/demodulator 224. In some embodiments, receive path 301 may include a low-noise amplifier (LNA), which is not shown in FIG. 3. In this embodiment, canceller 130 is also connected to receive demodulated baseband analog I and Q component signals from downconverter/demodulator 224. These demodulated I and Q component signals serve as an error signal in a feedback loop formed by canceller 130, coupler 302 and downconverter/demodulator 224.

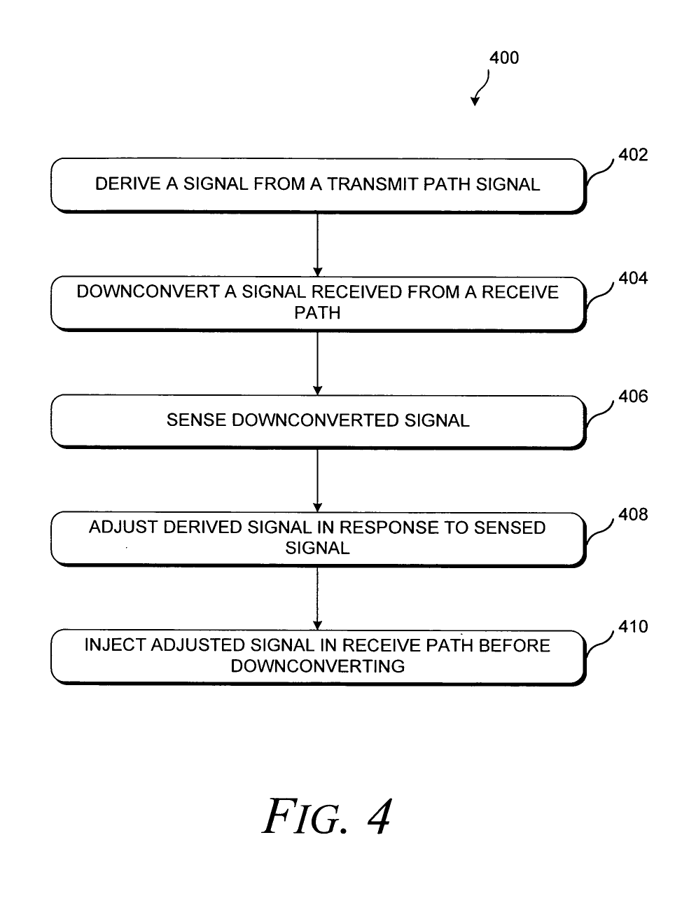

In this embodiment, downconverter/demodulator 224 is a part of a direct conversion receiver and thus, is used to downconvert backscatter signals received via antenna unit 222 (FIG. 2) directly to baseband while concurrently extracting the I and Q component signals. FIG. 4 illustrates operational flow of a canceller in canceling an interference signal, according to one embodiment. In one embodiment, the operational flow of FIG. 4 can be implemented using canceller 130 (FIG. 3) although in other embodiments different components may perform the operations.

In an operation 402, a signal is derived from a transmit path of a transceiver. In one embodiment, canceller 130 (FIG. 3) derives the signal from transmit path 300 (FIG. 3). For example, canceller 130 can obtain the derived signal via a coupler (not shown) in transmit path 300 in one embodiment, or directly from a LO of transceiver 110 (FIG. 2).

In an operation 404, a signal that is propagating on a receive path of a transceiver is downconverted. In one embodiment, downconverter/demodulator 224 downconverts the backscatter signal received via antenna unit 222 (FIG. 2) and propagated on receive path 301 (FIG. 3). For example, in one embodiment, downconverter/demodulator 224 is used to directly downconvert the received signal to baseband by mixing the received signal with a mixing signal having the same frequency as the carrier signal. This embodiment of downconverter/demodulator 224 can also concurrently demodulate the I and Q component signals by splitting the received backscatter signal and mixing one portion with the mixing signal and the other portion with the same mixing signal delayed by 90°. In one embodiment, these mixing signals are generated from the LO signal that is used to generate the carrier signal.

In an operation 406, the downconverted signal from operation 404 is sensed. In one embodiment, canceller 130 senses the downconverted I and Q component signals outputted by downconverter/demodulator 224. In another embodiment, the I and Q component signals are sensed by DSP 212 (FIG. 2). As previously described, the downconverted signal (e.g., the I and Q component signals) will have a DC component if the carrier feed-through signal reaches downconverter/demodulator 224. Based on this observation, in one embodiment, canceller 130 (or DSP 212) is configured to sense the DC components of the I and Q component signals of the downconverted signal.

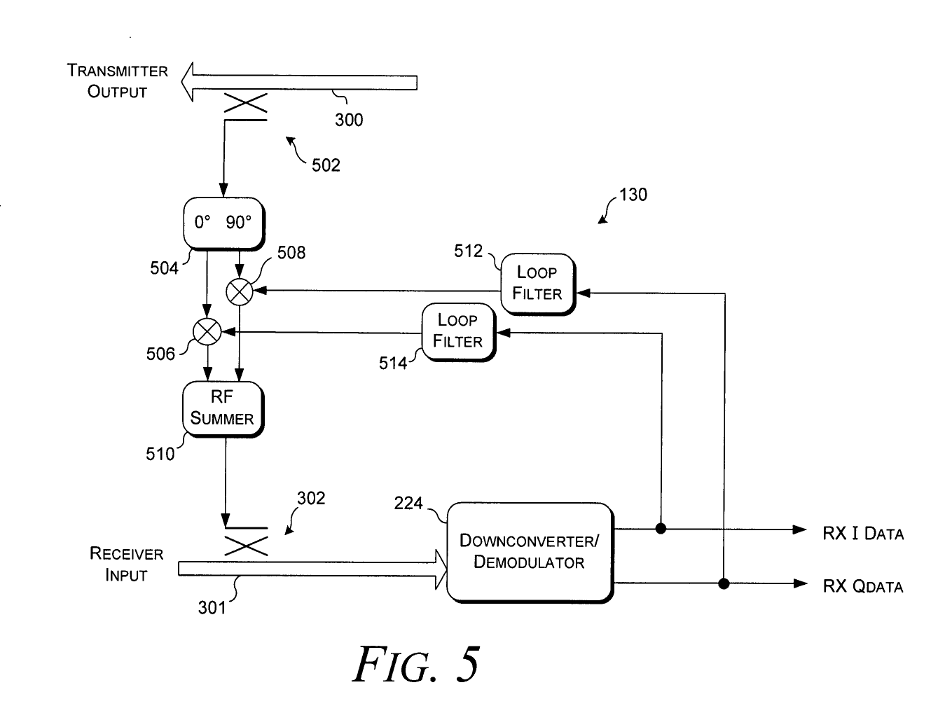

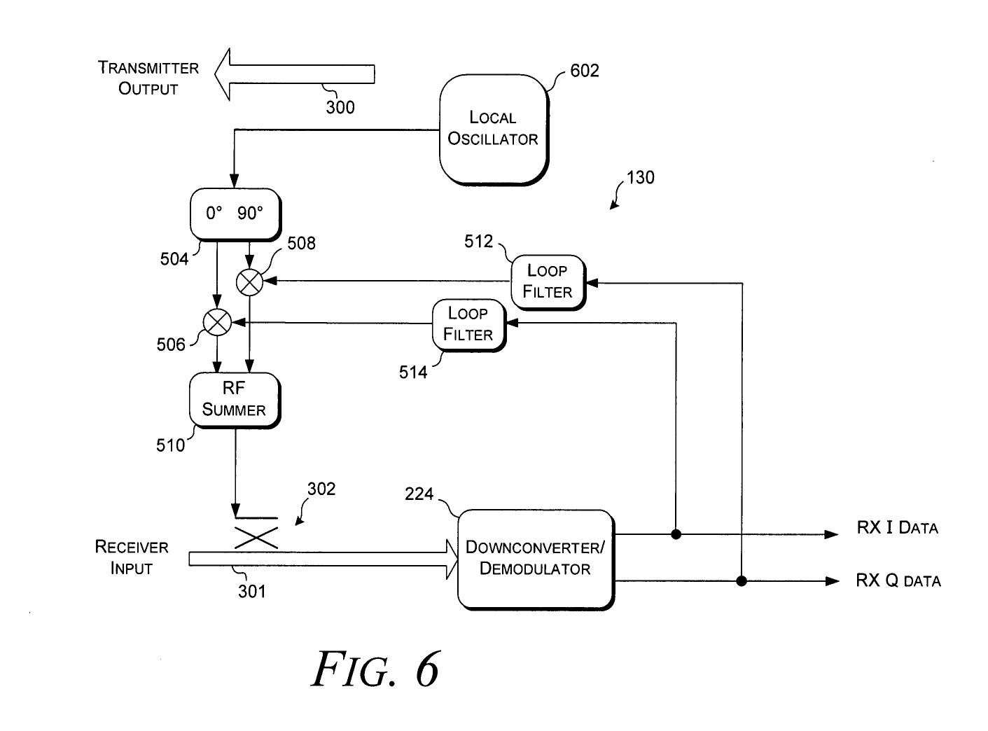

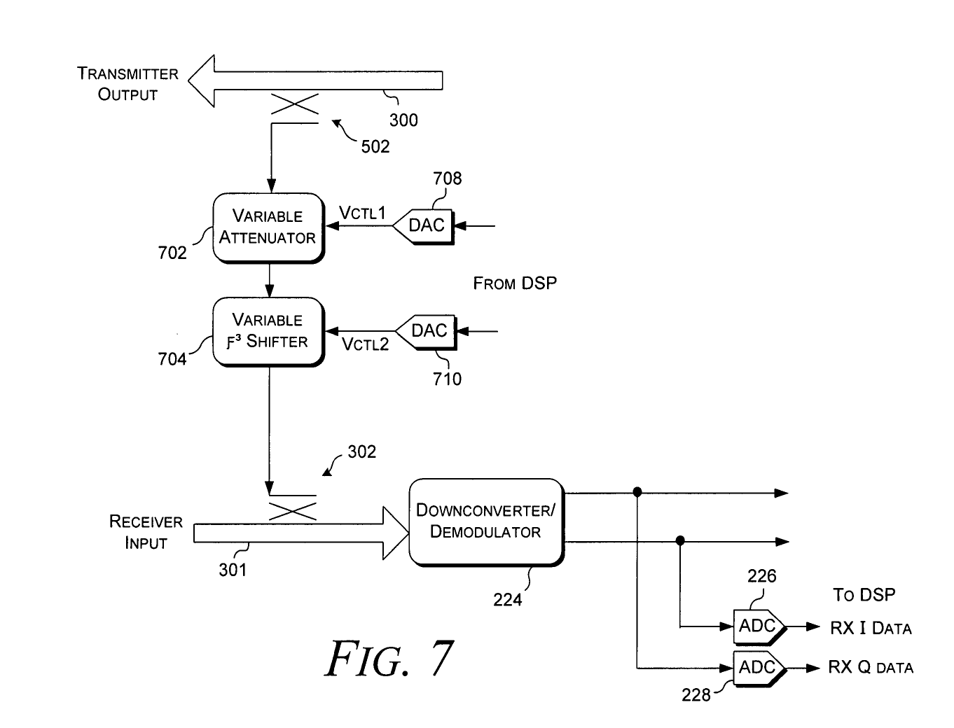

In an operation 408, the derived signal from operation 402 is adjusted in response to the sensed signal from operation 406. In one embodiment, canceller 130 then adjusts the amplitude and/or phase of the derived signal to form an adjustment signal in response to the sensed signal. Embodiments of canceller 130 and how canceller 130 can adjust the derived signal are described in more detail below. For example, Cartesian cancellation embodiments of canceller 130 are described in conjunction with FIGS. 5 and 6, and a polar cancellation embodiment is described in conjunction with FIG. 7.

In an operation 410, the adjusted signal from operation 408 is then injected into the receive path before downconverter/demodulator 224 so that the carrier feed-through signal can be canceled prior to downconverting a received backscattered signal. In one embodiment, coupler 302 (FIG. 3) receives the adjusted signal from canceller 130 and injects the adjusted signal into receive path 301. These operations implement a continuous feedback loop to cancel out the interference (i.e., carrier feed-through) signal.

FIG. 5 illustrates canceller 130 (FIG. 3), according to a Cartesian-based embodiment. In this embodiment, canceller 130 includes a coupler 502, a ninety-degree splitter 504, mixers 506 and 508, a RF summer 510, and loop filter units 512 and 514. In this embodiment, coupler 302 (FIG. 3) is implemented using a directional coupler to combine the adjustment signal from canceller 130 to receive path 301.

In operation, coupler 502 splits off a relatively small portion of the carrier signal propagating in transmit path 300. This split off signal serves as the derived signal in this embodiment. In one embodiment, coupler 502 is a directional coupler although other types of couplers can be used to implement coupler 502 in other embodiments.

Ninety-degree splitter 504 then divides the derived signal into two signals having substantially the same power but with a ninety-degree phase difference. One of the output signals corresponds to the I component signal of the derived signal and the other output signal corresponds to the Q component signal of the derived signal. In one embodiment, ninety-degree splitter 504 is implemented with a quadrature coupler (or 3 dB hybrid coupler). Other types of ninety-degree splitters can be used in other embodiments. Further, in some embodiments, ninety-degree splitter 504 can be omitted, with the derived signal being obtained directly from the I and Q component signals generated by modulator/upconverter 218.

Mixers 506 and 508 then multiply the two signals being input to each mixer. In this embodiment, mixer 506 receives the Q component signal from ninety-degree splitter 504 and the output signal from loop filter unit 512. Mixer 508 receives the I component signal from ninety-degree splitter 504 and the output signal from loop filter unit 514. Mixers 506 and 508 then each output a signal that represents the product of its input signals. Mixers 506 and 508 may be implemented using any suitable design.

RF summer 510 then combines the two signals received from mixers 506 and 508 without introducing any phase difference between the input signals. In this embodiment, RF summer 510 is implemented using any suitable zero-degree combiner. In effect, ninety-degree splitter 504, mixers 506 and 508 and RF summer 510 implement a vector modulator receiving “data signals” from loop filter units 512 and 514. As previously described, with appropriate selection of the data signals provided to a vector modulator, the carrier signal (i.e., the derived signal in this case) can be adjusted to have any desired amplitude and phase. In this embodiment, loop filter units 512 and 514 provide the data signals to cancel the carrier feed-through signal using a negative feedback technique as described below.

Loop filter units 512 and 514 are used to control the magnitude of the “data signals” inputted to mixers 508 and 506, respectively. That is, loop filter unit 512 filters out the backscatter spectrum from the Q component signal extracted by downconverter/demodulator 224 from the receive signal, passing, in effect the DC component which results from the carrier feed-through signal. Loop filter unit 512 then outputs a data signal to mixer 508 so that the Q component signal of the adjustment signal will cancel out the Q component signal of the carrier feed-through signal. Similarly, loop filter unit 514 filters out the backscatter spectrum from the I component signal extracted by downconverter/demodulator 224 from the receive signal. Loop filter unit 514 then outputs a data signal to mixer 506 so that the I component signal of the adjustment signal will cancel out the I component signal of the carrier feed-through signal. In one embodiment, loop filter units 512 and 514 are implemented using integrators circuits. In this embodiment, loop filter units 512 and 514 have a relatively low bandwidth to keep the feedback loop stabilized on the carrier frequency rather than the spectrum of the modulation of backscatter signals.

FIG. 6 illustrates canceller 130 (FIG. 3), according to another Cartesian-based embodiment. This alternative embodiment is substantially similar to the embodiment of FIG. 5 except that the derived signal is obtained from a LO 602 rather than from a coupler in transmit path 300. The embodiments of FIGS. 5 and 6 provide closed-loop analog implementations to cancel carrier feed-through interference.

FIG. 7 illustrates canceller 130 (FIG. 3), according to a polar-based embodiment. In this embodiment, canceller 130 includes a variable attenuator 702, a variable phase shifter 704, a DAC 708 connected to variable attenuator 702 and DSP 212 (FIG. 2), and a DAC 710 connected to variable phase shifter 704 and DSP 212. DSP 212 is configured to detect the DC components of the I and Q component signals received from downconverter/demodulator 224 via ADCs 226 and 228 and to generate appropriate control signals for DACs 708 and 710 to adjust the derived signal to have an amplitude and phase that cancels the carrier feed-through signal. DSP 212 implements a negative feedback loop in software to cancel the carrier feed-through interference using variable attenuator 702 and variable phase shifter 704. Although in this embodiment the derived signal is obtained from transmit path 300 via coupler 502, in some other embodiments the derived signal can be obtained from a LO as in the embodiment of FIG. 6.

In applications in which the carrier feed through interference and canceller performance is expected to stay relatively stable over time, the cancellation system need not use continuous feedback. For example, DSP 212 can have a look-up table (LUT) that is determined empirically to cancel out the carrier feed-through interference. In some embodiments, the settings for the canceller (for both Cartesian-based and polar-based embodiments) can be determined when the system is initiated using training techniques. The settings can be updated to account for changes in performance due to environmental factors such as aging, wear, temperature cycling, etc. Still further, other embodiments use an analog implementation of the non-continuous feedback loop. For example, an adjustable voltage regulator can be used to provide analog control of canceller settings.

In an alternative embodiment, canceller 130 is substantially similar to canceller 130 of FIG. 6 except that loop filters 512 and 514 are omitted and DSP 212 is programmed to implement the functions of loops filters 512 and 514.

Reference has been made throughout this specification to “one embodiment,” “an embodiment,” or “an example embodiment” meaning that a particular described feature, structure, or characteristic is included in at least one embodiment of the present invention. Thus, usage of such phrases may refer to more than just one embodiment. Furthermore, the described features, structures, or characteristics may be combined in any suitable manner in one or more embodiments.

In addition, embodiments of the present invention may be implemented not only with physical components (e.g., within a semiconductor chip), but also within machine-readable media. For example, the designs described above may be stored upon and/or embedded with machine readable media associated with a design tool used for designing semiconductor devices. Examples include designs defined/formatted in VHSIC Hardware Description Language (VHDL), Verilog language and SPICE language. Some netlist examples include: a behavior level netlist, a register transfer level (RTL) netlist, a gate level netlist, and a transistor level netlist. Machine readable media also include media having layout information such as a GDS-II file. Further, netlist files or other machine-readable media for semiconductor chip design may be used in a simulation to perform the methods of the embodiments disclosed herein.

Thus, embodiments of the present invention may be used as or to support software program executed upon some form of processing core (e.g., a CPU of a computer) or otherwise implemented or realized upon or within a machine-readable medium. A machine-readable medium includes any mechanism for storing or transmitting information in a form readable by a machine (e.g. a computer). For example, a machine-readable medium can include read only memory (ROM), random access memory (RAM), magnetic disk storage media, optical storage media, flash memory devices, etc. In addition, machine-readable media can include propagated signals such as electrical, optical, acoustical or other form of propagated signal (e.g., carrier wave signals, infrared signals, digital signals, etc.)

One skilled in the relevant art may recognize, however, that the invention may be practiced without one or more of the specific details, or with other methods, resources, materials, etc. In other instances, well known structures, resources, or operations have not been shown or described in detail merely to avoid obscuring aspects of the invention.

While example embodiments and applications have been illustrated and described, it is to be understood that the invention is not limited to the precise configuration and resources described above. Various modifications, changes, and variations apparent to those skilled in the art may be made in the arrangement, operation, and details of the methods and systems of the present invention disclosed herein without departing from the scope of the claimed invention.

What is claimed is:

1. A circuit for canceling an interference signal, the circuit comprising:
a receive path that includes a downconverter, the downconverter to output a first signal related to the interference signal;
a canceller to output a second signal that is related to the first signal; and
a first coupler to couple the second signal into the receive path before the downconverter.

2. The circuit of claim 1 further comprising a transmit path to propagate a transmit signal, wherein the first signal is also related to a signal derived from the transmit signal.

3. The circuit of claim 2 wherein the transmit path includes a source of non-coherent noise, and wherein the first signal includes non-coherent noise derived from the source.

4. The circuit of claim 3 wherein the source comprises a modulator.

5. The circuit of claim 2 further comprising a second coupler coupled to the transmit path, wherein the derived signal is an output signal of the second coupler.

6. The circuit of claim 1 further comprising a local oscillator to output an oscillating signal, wherein the second signal is also related to a signal derived from the oscillating signal.

7. The circuit of claim 1 wherein the second signal includes in-phase (I) component and quadrature (Q) component signals derived from I and Q signals outputted by the downconverter.

8. The circuit of claim 7 wherein the I and Q component signals of the second signal are summed before being output by the canceller.

9. The circuit of claim 7 further comprising first and second filters to respectively filter the I and Q component signals outputted by the downconverter.

10. The circuit of claim 1 wherein the canceller is to selectively adjust an amplitude or a phase or both the amplitude and phase of the second signal in response to the first signal.

11. The circuit of claim 1 wherein the canceller comprises a processor unit to generate the second signal based on signals outputted by the downconverter.

12. A computer-readable medium having stored thereon a design of a circuit according to claim 1.

13. A method to cancel an interference signal in a RFID transceiver, the method comprising:
downconverting a signal propagating in a receive path that includes a downconverter;
sensing the downconverted signal;
providing an adjustment signal that depends on the sensed signal; and
coupling the adjustment signal into the receive path upstream from the downconverter.

14. The method of claim 13 further comprising deriving a signal from a transmit signal propagating in a transmit path to form a derived signal, wherein the adjustment signal also depends on the derived signal.

15. The method of claim 14 wherein the transmit path includes a source of non-coherent noise, and wherein the first signal includes non-coherent noise derived from the source.

16. The method of claim 15 wherein the source comprises a modulator.

17. The method of claim 14 wherein providing an adjustment signal comprises adjusting the derived signal in response to the sensed signal.

18. The method of claim 13 wherein providing an adjustment signal comprises adjusting a signal derived from a local oscillator signal in response to the sensed signal.

19. The method of claim 13 wherein sensing the downconverted signal comprises sensing in-phase (I) and quadrature (Q) component signals of the downconverted signal.

20. The method of claim 19 wherein providing an adjustment signal comprises adjusting I and Q component signals of the adjustment signal in response to the sensed I and Q component signals.

21. The method of claim 13, wherein providing an adjustment signal comprises adjusting a magnitude or a phase or both the magnitude and phase of the adjustment signal in response to the sensed signal.

22. The method of claim 21, wherein adjusting a magnitude or a phase or both the magnitude and phase of the adjustment signal, further comprises determining an adjustment of the magnitude or phase or both the magnitude and phase from I and Q component signals of the sensed signal.

23. An apparatus to cancel an interference signal in a RFID transceiver, the apparatus comprising:
means for downconverting a signal propagating in a receive path;
means for sensing the downconverted signal;
means for providing an adjustment signal that depends on the sensed signal; and
means for coupling the adjustment signal into the receive path before downconverting.

24. The apparatus of claim 23 further comprising means for deriving a signal from a transmit signal propagating in a transmit path, wherein the adjustment signal also depends on the derived signal.

25. The apparatus of claim 24 wherein the transmit path includes a source of non-coherent noise, and wherein the first signal includes non-coherent noise derived from the source.

26. The apparatus of claim 25 wherein the source comprises a modulator.

27. The apparatus of claim 24 wherein the means for providing an adjustment signal comprises means for adjusting the derived signal in response to the sensed signal.

28. The apparatus of claim 23 further comprising a local oscillator, wherein the means for providing an adjustment signal is to adjust an output signal of the local oscillator in response to the sensed signal.

29. The apparatus of claim 23 wherein the means for sensing the downconverted signal comprises means for sensing in-phase (I) and quadrature (Q) component signals of the downconverted signal.

30. The apparatus of claim 29 wherein the means for providing an adjustment signal comprises means for adjusting I or Q or both I and Q component signals of the adjustment signal in response to the sensed I and Q component signals.

31. The apparatus of claim 23 wherein the means for providing an adjustment signal comprises means for adjusting a magnitude or a phase or both the magnitude and phase of the adjustment signal in response to the sensed signal.

32. The apparatus of claim 31 wherein the means for adjusting a magnitude and phase of the adjustment signal comprises means for determining a magnitude and phase adjustment from I and Q component signals of the sensed signal.

33. A computer-readable medium having stored thereon a design of an apparatus according to claim 23.

34. A circuit to cancel carrier signal interference in a RFID system having a downconverter used in receiving a modulated signal, the circuit comprising:
a first coupler to output a signal derived from a carrier signal of the RFID system;
an adjustment circuit to adjust the derived signal as a function of an output signal of the downconverter; and
a second coupler to combine the adjusted signal and a signal received by a RFID reader before being downconverted by the downconverter.

35. The circuit of claim 34 wherein the adjustment circuit comprises:
a filter circuit to filter in-phase (I) and quadrature (Q) component signals of the downconverted signal; and
a vector modulator to receive I and Q component signals of the derived signal and the filtered I and Q component signals of the downconverted signal.

36. The circuit of claim 34 wherein the adjustment circuit comprises:
an analog-to-digital converter circuit to convert I and Q component signals of the downconverted signal into digital samples;
a processor unit to determine magnitude and phase adjustments from the digital samples of the I and Q component signals;
an attenuator to adjust a magnitude of the derived signal in response to magnitude adjustments from the processor unit; and
a phase adjustor to adjust a phase of the derived signal in response to phase adjustments from the processor unit.

37. The circuit of claim 34 wherein the adjustment circuit comprises a continuous feedback loop.

38. The circuit of claim 37 wherein the continuous feedback loop is an analog feedback loop.

39. The circuit of claim 37 wherein the continuous feedback loop comprises a digital circuit.

40. The circuit of claim 34 wherein the adjustment circuit is to perform a non-continuous adjustment.

41. The circuit of claim 40 wherein the adjustment circuit comprises an analog circuit.

42. The circuit of claim 40 wherein the adjustment circuit comprises a digital circuit.

43. A reader for use in an RFID system, the reader comprising:
a transmit path to propagate a carrier signal of the RFID system;
a first coupler to output a signal derived from the carrier signal;
a receive path including a direct conversion receiver;
an adjustment circuit to adjust the derived signal as a function of an output signal of the direct conversion receiver; and
a second coupler to inject the adjusted signal into the receive path upstream from the direct conversion receiver.

44. The reader of claim 43 wherein the transmit path includes a source of non-coherent noise, and wherein the first signal includes non-coherent noise derived from the source.

45. The reader of claim 44 wherein the source comprises a modulator.

46. The reader of claim 43 wherein the adjustment circuit comprises:
a filter circuit to filter in-phase (I) and quadrature (Q) component signals of the output signal of the direction conversion receiver; and
a vector modulator to receive I and Q component signals of the derived signal and the filtered I and Q component signals from the filter circuit.

47. The reader of claim 43 wherein the adjustment circuit comprises:
an analog-to-digital converter circuit to convert I and Q component signals of the output signal of the direct conversion receiver into digital samples;
a processor unit to determine magnitude and phase adjustments from the digital samples of the I and Q component signals;
an attenuator to adjust a magnitude of the derived signal in response to magnitude adjustments from the processor unit; and
a phase adjustor to adjust a phase of the derived signal in response to phase adjustments from the processor unit.

48. The circuit of claim 43 wherein the adjustment circuit comprises a continuous feedback loop.

49. The circuit of claim 48 wherein the continuous feedback loop is an analog feedback loop.

50. The circuit of claim 48 wherein the continuous feedback loop comprises a digital circuit.

51. The circuit of claim 43 wherein the adjustment circuit is to perform a non-continuous feedback adjustment.

52. The circuit of claim 51 wherein the adjustment circuit comprises an analog circuit.

53. The circuit of claim 51 wherein the adjustment circuit comprises a digital circuit.
